(19) United States
(12) Patent Application Publication
(10) Pub. No.: US 2013/0285761 A1
(43) Pub. Date: Oct. 31, 2013

(54) VARIABLE CAPACITOR MODULE

(71) Applicant: SAMSUNG ELECTRO-MECHANICS CO., LTD., Suwon (KR)

(72) Inventor: Sang Wook PARK, Suwon (KR)

(73) Assignee: SAMSUNG ELECTRO-MECHANICS CO., LTD., Suwon (KR)

(21) Appl. No.: 13/800,282

(22) Filed: Mar. 13, 2013

(30) Foreign Application Priority Data
Apr. 27, 2012 (KR) 10-2012-0044770

(51) Int. Cl. H03H 7/38

(52) U.S. Cl. CPC H03H 7/38
USPC 333/32

(57) ABSTRACT

Disclosed herein is a variable capacitor module, including: a capacitor circuit part including a plurality of capacitor units connected in parallel with each other; and a switching circuit part including a plurality of switch units connected between the plurality of capacitor units, and varying a capacitance of the capacitor circuit part by selecting at least one capacitor unit according to operations of the switch units, and thus, an asymmetric phenomenon where the RF terminal has directivity by gate resistance of the switch can be removed.

### CROSS REFERENCE(S) TO RELATED APPLICATIONS

This application claims the benefit under 35 U.S.C. Section 119 of Korean Patent Application Serial No. 10-2012-0044770, entitled “Variable Capacitor Module” filed on Apr. 27, 2012, which is hereby incorporated by reference in its entirety into this application.

### BACKGROUND OF THE INVENTION

1. Technical Field

The present invention relates to a variable capacitor module, and more particularly to a variable capacitor module applicable in a tunable matching network (TMN) of a wireless communication device.

2. Description of the Related Art

Recently, with the rapid development of wireless communication technology, 4 generation (4G) mobile communication represented by long term evolution (LTE) has emerged in addition to current 3 generation (3G) mobile communication, and as functions of the 3G mobile communication network are added to those of the 4G mobile communication network, the number of types that needs to be supported by mobile phones is increasing.

Therefore, in view of current RF functions, various frequency bands need to be covered by using one RF chain, and the power consumed by a power amplifier (PA) needs to be optimized by optimizing front-end matching including an antenna while using a mobile phone.

In order to implement the above function, flexibility is supplemented by adding a tunable matching network circuit to the existing RF front end having a fixed structure, and in order to vary the matched value such as impedance or the like depending on the varied conditions, a variable capacitor module was used in the related art.

FIG. 1 is a schematic diagram of a variable capacitor module according to the related art.

Referring to FIG. 1, a variable capacitor module includes a plurality of capacitor elements C, 2C, 4C, 8C, and 16C connected in parallel between an RF input terminal (RF in) and an RF output terminal (RF out), and switch elements SW1˜SW5 connected in series to the capacitor elements C, 2C, 4C, 8C, and 16C. The switch elements SW1˜SW5 are controlled to be operated, thereby varying desired capacitances (C˜31C). Here, in the variable capacitor module, one of the important figure-of-merits is a quality factor, and this quality factor is largely influenced by a resistance component.

In the tunable matching network circuit, one of an RF+ terminal and an RF− terminal is connected to a signal and the other thereof is connected to a ground, and the quality factor is different for each of the cases. The main reason is that, while the switch element is in an ON operation, an equivalent resistance in the case where the RF+ terminal is connected to the signal is calculated as if it is connected in parallel with resistors connected to a switch element of FIG. 1 and an equivalent resistance in the case where the RF-terminal is connected to the signal is calculated as if it is connected in parallel with capacitor elements.

In configuring the tunable matching network circuit, different characteristics are exhibited depending on directions of the variable capacitor module, and thus, the risk of manufacturing defects is increasing, and additional costs for management thereof occur.

### RELATED ART DOCUMENT

U.S. Patent Laid-Open Publication No. 2011/0002080A1

### SUMMARY OF THE INVENTION

An object of the present invention is to provide a variable capacitor module capable of improving a quality factor by employing a structure where a plurality of switch units are connected to each other between a plurality of capacitor units connected in parallel with each other, and implementing uniform characteristics regardless of connection directivity with a tunable matching network.

According to an exemplary embodiment of the present invention, there is provided a variable capacitor module, including: a capacitor circuit part including a plurality of capacitor units connected in parallel with each other; and a switching circuit part including a plurality of switch units connected between the plurality of capacitor units, and varying a capacitance of the capacitor circuit part by selecting at least one capacitor unit according to operations of the switch units.

The switch unit may be connected between two electrodes included in two capacitor units selected from the plurality of capacitor units.

The switch unit may include: a first switch unit connected between two first electrodes included in two capacitor units selected from the plurality of capacitor units; and a second switch unit connected between two second electrodes included in two capacitor units selected from the plurality of capacitor units.

The first electrode may be a positive (+) electrode included in the capacitor unit, and the second electrode may be a negative (−) electrode included in the capacitor unit.

The capacitor unit may be composed of at least one capacitor.

Here, when the capacitor unit is composed of two or more capacitors, the capacitors may be connected in series with each other.

The switch unit may be composed of at least one switch.

Here, when the switch unit is composed of two or more switches, the switches may be connected in series with each other.

The variable capacitor module may further include a plurality of RF terminals connectable with electrodes included in the plurality of capacitor units.

The RF terminals may include: a plurality of first RF terminals connectable with first electrodes included in the plurality of capacitor units; and a plurality of second RF terminals connectable with second electrodes included in the plurality of capacitor units.

Here, any one first RF terminal and any one second RF terminal selected from the plurality of first terminals and second RF terminals may be used as an RF input terminal and an RF output terminal, respectively.

The first and second RF terminals may be electrically insulated from each other.

According to another exemplary embodiment of the present invention, there is provided a variable capacitor module, including: a capacitor circuit part including a first capacitor unit and a second capacitor unit connected in parallel with the first capacitor unit; and a switching circuit part including a first switch unit connected between first electrodes included in the first and second capacitor units and a second switch unit connected between second electrodes included in the first and second capacitor units, and varying a capacitance of the capacitor circuit part by selecting at least one from the first and second capacitor units according to operations of the first and second switch units.

The variable capacitor module may further include: 1a-th and 1b-th RF terminals connectable to first electrodes included in the first and second capacitor units, respectively; and 2a-th and 2b-th RF terminals connectable to second electrodes included in the first and second capacitor units, respectively.

The switching circuit part may increase the capacitance of the capacitor circuit part by selecting the first and second capacitor units according to ON operations of the first and second switch units when the 1a-th and 2a-th RF terminals of the first capacitor unit are selected as an RF input terminal and an RF output terminal.

The switching circuit part may output the capacitance of the first capacitor unit as the capacitance of the capacitor circuit part by selecting the first capacitor unit according to OFF operations of the first and second switch units when the 1a-th and 2a-th RF terminals of the first capacitor unit are selected as an RF input terminal and an RF output terminal.

According to still another exemplary embodiment of the present invention, there is provided a variable capacitor module, including: a capacitor circuit part including 11-th to 13-th capacitor units connected in parallel with each other; and a switching circuit part including a 11a-th switch unit connected between first electrodes included in the 11-th and 12-th capacitor units; a 12a-th switch unit connected between second electrodes included in the 11-th and 12-th capacitor units; a 11b-th switch unit connected between first electrodes included in the 12-th and 13-th capacitor units; a 12b-th switch unit connected between second electrodes included in the 12-th and 13-th capacitor units; a 11c-th switch unit connected between first electrodes included in the 11-th and 13-th capacitor units; and a 12c-th switch unit connected between second electrodes included in the 11-th and 13-th capacitor units, the switching circuit part varying a capacitance of the capacitor circuit part by selecting at least one capacitor unit from the 11-th to 13-th capacitor units according to operations of the 11a-th to 11c-th switch units and the 12a-th to 12c-th switch units.

The variable capacitor module may further include: 11c-th, 11b-th, and 11c-th RF terminals connectable to the first electrodes included in the 11-th, 12-th, and 13-th capacitor units, respectively; and 12a-th, 12b-th, and 12c-th RF terminals connectable to the second electrodes included in the 11-th, 12-th, and 13-th capacitor units, respectively.

### BRIEF DESCRIPTION OF THE DRAWINGS

FIG. 1 is a schematic diagram of a variable capacitor module according to the related art.

FIG. 2 is a diagram of a wireless communication device according to an exemplary embodiment of the present invention.

FIG. 3 is a detailed diagram of a tunable matching network circuit part.

FIG. 4 is a diagram of a variable capacitor module according to an exemplary embodiment of the present invention.

FIG. 5 shows a case where a capacitor unit is composed of a plurality of capacitors in FIG. 4.

FIG. 6 shows a case where a switch unit is composed of a plurality of switches in FIG. 4.

FIG. 7 shows a case where a capacitor unit is composed of a plurality of capacitors and a switch unit is composed of a plurality of switches in FIG. 4.

FIG. 8 is a diagram of a variable capacitor module according to another exemplary embodiment of the present invention.

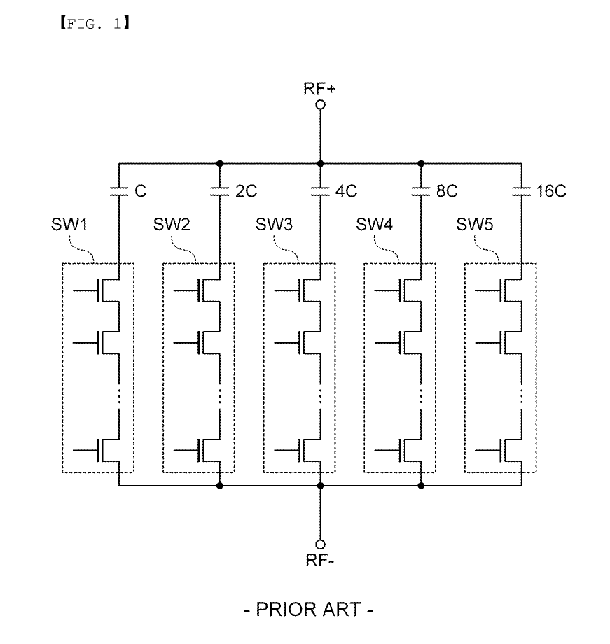

### DESCRIPTION OF THE PREFERRED EMBODIMENTS

Terms and words used in the present specification and claims are not to be construed as a general or dictionary meaning but are to be construed as meaning and concepts meeting the technical ideas of the present invention based on a principle that the inventors can appropriately define the concepts of terms in order to describe their own inventions in best mode.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

Hereinafter, embodiments of the present invention will be described with reference to the accompanying drawings.

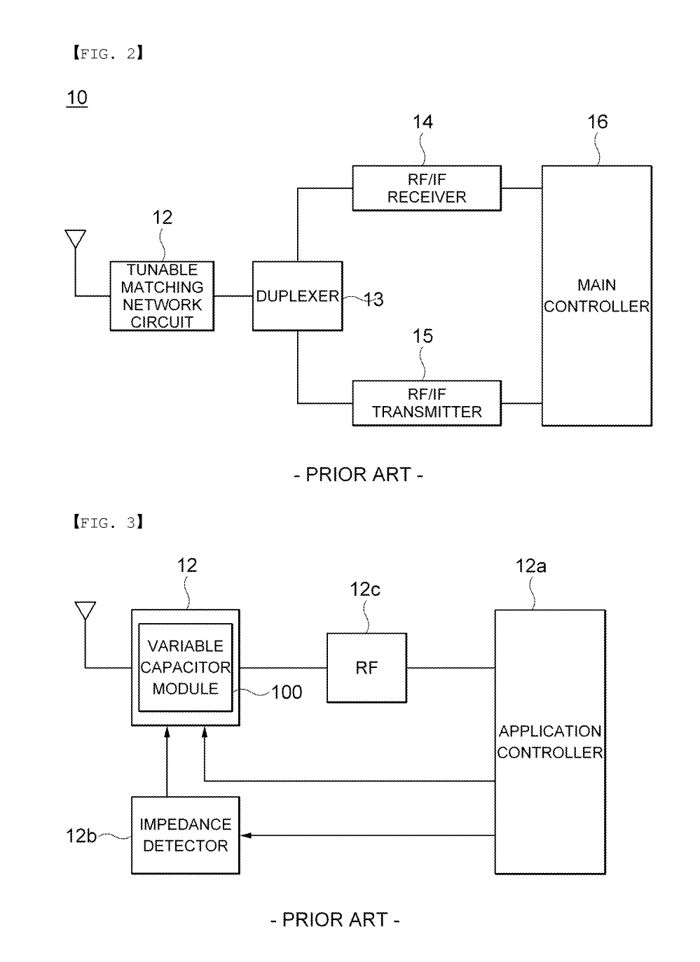

FIG. 2 is a diagram of a wireless communication device according to an exemplary embodiment of the present invention.

As shown in FIG. 2, a wireless communication device 10 includes a tunable matching network circuit part 12, a duplex 13, an RF/IF receiver 14, an RF/IF transmitter 15, and a main controller 16.

The tunable matching network circuit part 12 may be composed of inductors, capacitors, and the like. The tunable matching network circuit 12 may change a capacitance by using a variable capacitor module, to thereby have a variable impedance value, and may change the entire impedance value. The tunable matching network may perform antenna matching by changing the entire impedance value according to the used environment.

The duplexer 13 serves to separate transmission and reception signals at an antenna. The RF/IF receiver 14 converts a signal received through the duplexer 13 into a baseband signal to transfer the signal to the main controller 16, and includes a low noise amplifier, a band pass filter, a power amplifier, and the like, for lowering a noise figure of the received signal.

The RF/IF transmitter 15 converts the baseband signal generated in the main controller 16 into a signal transmittable through a mobile communication network, and includes a power amplifier, a band pass filter, and the like.

The main controller 16 controls the entire operations of the wireless communication device, and outputs a control signal for antenna matching.

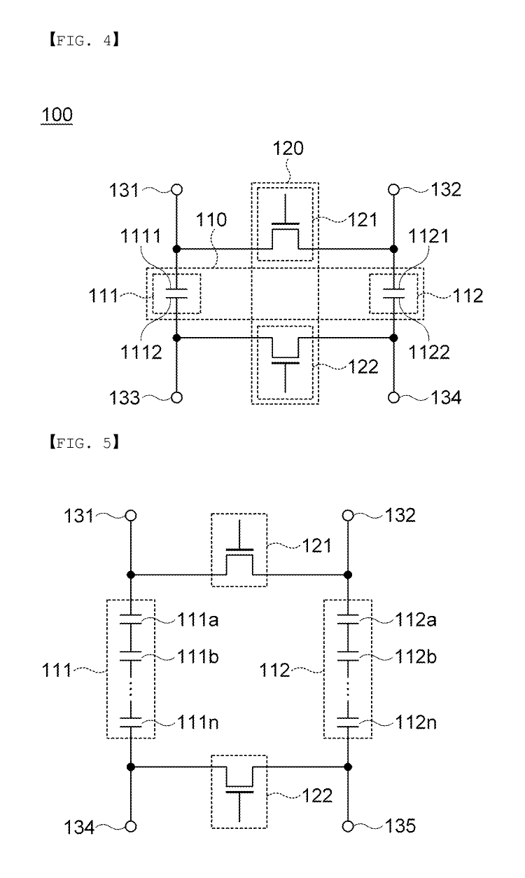

FIG. 3 is a detailed diagram of the tunable matching network circuit part. Referring to FIG. 3, the tunable matching network circuit part 12 varies a capacitance in order to improve power transfer efficiency from the power amplifier to the antenna, and may include a variable capacitor module 100, an application controller 12a, and an impedance detector 12b.

Here, the tunable matching network circuit part 12 may adjust the capacitance by using an open loop manner and a closed loop manner. According to the open loop manner, the capacitance is adjusted by the application controller 12a with reference to a previously stored look-up table. According to the closed loop manner, the capacitance is adjusted depending on the conditions based on the signal detected by the impedance detector 12b.

FIG. 4 is a diagram of the variable capacitor module according to an exemplary embodiment of the present invention.

Referring to FIG. 4, the variable capacitor module 100 may include a capacitor circuit part 110 having a plurality of capacitor units 111 and 112, and a switching circuit part 120 having a plurality of switch units 121 and 122 and varying a capacitance of the capacitor circuit part 110 by selecting at least one of the capacitor units according to operations of the switch units.

The capacitor circuit part 110 may be composed of a plurality of capacitor units 111 and 112, which may be connected in parallel with each other. Also, the capacitor unit may be composed of at least one capacitor.

The switching circuit part 120 may be composed of a plurality of switch units 121 and 122, which may be connected between two capacitor units 111 and 112 directly connected to each other among the plurality of capacitor units 111 and 112. More specifically, the switching circuit part 120 may be connected between electrodes included in the two capacitor units 111 and 112. The switching circuit part 120 may include a first switch unit 121 connected between first electrodes 1111 and 1121 included in the two capacitor units 111 and 112 and a second switch unit 122 connected between second electrodes 1112 and 1122 included in the two capacitor units 111 and 112.

In addition, the switch unit may be composed of at least one switch.

For example, the variable capacitor module may be composed of the first capacitor unit 111 and the second capacitor unit 112 connected in parallel with the first capacitor unit 111, and may include the first switch unit 121 connected between the first electrodes 1111 and 1121 included in the first and second capacitor units 111 and 112 and the second switch unit 122 connected between the second electrodes 1112 and 1122 included in the first and second capacitor units 111 and 112. By employing this structure, the entire capacitance can be changed through the effect of increasing or decreasing the areas of the electrodes included in the capacitors according to ON/OFF operations of the first and second switch units. Here, the first electrode may be a positive (+) electrode included in the capacitor unit and the second electrode may be a negative (−) electrode included in the capacitor unit.

If the first capacitor unit has a capacitance of 2C and the second capacitor unit has a capacitance of 4C, the entire capacitance may be 6C when all the first and second switch units are in an ON operation.

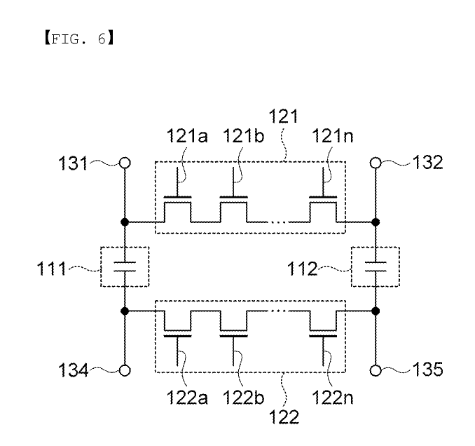

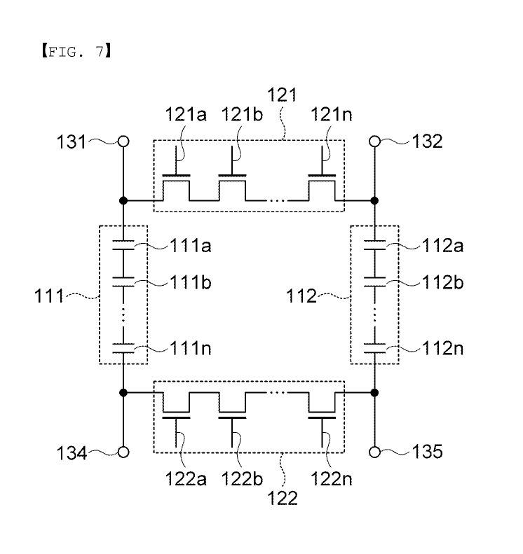

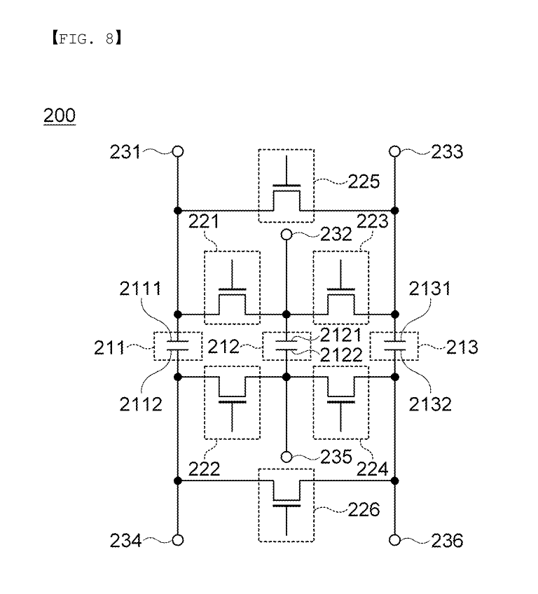

FIG. 5 shows a case where a capacitor unit is composed of a plurality of capacitors in FIG. 4; FIG. 6 shows a case where a switch unit is composed of a plurality of switches in FIG. 4; and FIG. 7 shows a case where a capacitor unit is composed of a plurality of capacitors and a switch unit is composed of a plurality of switches in FIG. 4. As shown in FIG. 5, the capacitor units 111 and 112 may have one or more capacitors 111a-111n and 112a-112n connected in series with each other, respectively. As shown in FIG. 6, the switch units 121 and 122 may have one or more switches 121a-121n and 122a-122n connected in series with each other, respectively. This is for distributing the voltage in order to bear high RF power (power handling) of a wireless communication device.

In addition, as shown in FIG. 7, the capacitor units 111 and 112 may have one or more capacitors 111a-111n and 112a-112n connected in series with each other, respectively, and the switch units 121 and 122 may have one or more switches 121a-121n and 122a-122n connected in series with each other, respectively.

Meanwhile, the variable capacitor module 100 according to an exemplary embodiment of the present invention may further include a plurality of first RF terminals 131 and 132 connected to the first electrodes 1111 and 1121 of the plurality of capacitor units 111 and 112 and a plurality of second RF terminals 133 and 134 connected to the second electrodes 1112 and 1122 of the plurality of capacitor units 111 and 112. That is, in FIG. 4, the first RF terminal may be composed of 1a-th and 1b-th RF terminals 131 and 133 and connected to the first and second electrodes 1111 and 1112 of the first capacitor unit 111, respectively. The second RF terminal may be composed of 2a-th and 2b-th RF terminals 132 and 134 and connected to the first and second electrodes 1121 and 1122 of the second capacitor unit 112, respectively. The first and second RF terminals may be electrically insulated from each other.

More specifically, since the first and second electrodes included in the plurality of capacitor units may be connected with pads usable as the RF terminals, a reference capacitor unit can be selected according to the range of a desired capacitance. Therefore, this is favorable in view of the quality factor since an ON resistor of the switch is not added to a corresponding reference capacitor unit.

For example, if the first capacitor unit between the first and second capacitor units is selected as a reference capacitor, the 1a-th and 1b-th terminals of the first capacitor unit may be connected with another circuit through wire bonding. Then, when the first and second switch units are OFF-operated, the capacitance of the first capacitor unit is the entire capacitance, and when all the first and second switch units are ON-operated, the sum of the capacitances of the first and second capacitor units is the entire capacitance.

FIG. 8 is a diagram of a variable capacitor module according to another exemplary embodiment of the present invention.

As shown in FIG. 8, a variable capacitor module 200 may include a capacitor circuit part 210 and a switching circuit part 220. The capacitor circuit part 210 may include 11-th to 13-th capacitor units 211, 212, and 213 connected in parallel with each other. The switching circuit part 220 may include a 11a-th switch unit 221 connected between first electrodes 2111 and 2121 of the 11-th and 12-th capacitor units 211 and 212; a 12a-th switch unit 222 connected between second electrodes 2112 and 2122 of the 11-th and 12-th capacitor units 211 and 212; a 11b-th switch unit 223 connected between first electrodes 2121 and 2131 of the 12-th and 13-th capacitor units 212 and 213; a 12b-th switch unit 224 connected between second electrodes 2122 and 2132 of the 12-th and 13-th capacitor units 212 and 213; a 11c-th switch unit 225 connected between first electrodes 2111 and 2131 of the 11-th and 13-th capacitor units 211 and 213; and a 12c-th switch unit 226 connected between second electrodes 2112 and 2132 of the 11-th and 13-th capacitor units 211 and 213.

In addition, the switching circuit part 220 varies the capacitance of the capacitor circuit part 210 by selecting at least one capacitor unit from the 11-th to 13-th capacitor units 211, 212, and 213 according to the operations of the 11a-th to 11c-th switch units 221, 223, and 225 and the 12a-th to 12c-th switch units 222, 224, and 226.

Here, the variable capacitor module 200 may further include 11a-th, 11b-th, and 11c-th RF terminals 231, 232, and 233 respectively connectable to the first electrodes 2111, 2121, and 2131 of the 11-th, 12-th, and 13-th capacitor units 211, 212, and 213, and 12a-th, 12b-th, and 12c-th RF terminals 234, 235, and 236 respectively connectable to the second electrodes 2112, 2122, and 2132 of the 11-th, 12-th, and 13-th capacitor units 211, 212, and 213.

For example, more specifically, in the case where the 11-th to 13-th capacitor units have capacitances of C0, C1, and C2, respectively, and the 12-th capacitor unit is a reference capacitor, the entire capacitance may be C0+C1 when the 11-th and 12-th capacitors are ON-operated; the entire capacitance may be C1+C2 when the 12-th and 13-th capacitors are ON-operated; and the entire capacitance may be C0+C1+C2 when all the switch units are ON-operated.

As set forth above, according to the variable capacitor module according to an exemplary embodiment of the present invention, an asymmetric phenomenon where the RF terminal has directivity by gate resistance of the switch can be removed by employing a structure where the plurality of switch units are respectively connected between the electrodes included in the plurality of capacitor units connected in parallel with each other.

Further, all the plurality of capacitor units are RF terminals, respectively, and thus, a reference capacitor unit can be selected according to the desired capacitance range, so that ON resistors of the switch need not be added to a corresponding reference capacitor unit, and this is advantageous in view of quality factor.

Further, a smaller number of switches or a smaller chip area is used as compared with the variable capacitor module of the related art, and thus, the quality factor can be further improved.

The present invention has been described in connection with what is presently considered to be practical exemplary embodiments. Although the exemplary embodiments of the present invention have been described, the present invention may be also used in various other combinations, modifications and environments In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A variable capacitor module, comprising:
a capacitor circuit part including a plurality of capacitor units connected in parallel with each other; and
a switching circuit part including a plurality of switch units connected between the plurality of capacitor units, and varying a capacitance of the capacitor circuit part by selecting at least one capacitor unit according to operations of the switch units.

2. The variable capacitor module according to claim 1, wherein the switch unit is connected between two electrodes included in two capacitor units selected from the plurality of capacitor units.

3. The variable capacitor module according to claim 1, wherein the switch unit includes:
a first switch unit connected between two first electrodes included in two capacitor units selected from the plurality of capacitor units; and
a second switch unit connected between two second electrodes included in two capacitor units selected from the plurality of capacitor units.

4. The variable capacitor module according to claim 3, wherein the first electrode is a positive (+) electrode included in the capacitor unit, and the second electrode is a negative (−) electrode included in the capacitor unit.

5. The variable capacitor module according to claim 1, wherein the capacitor unit is composed of at least one capacitor.

6. The variable capacitor module according to claim 5, wherein, when the capacitor unit is composed of two or more capacitors, the capacitors are connected in series with each other.

7. The variable capacitor module according to claim 1, wherein the switch unit is composed of at least one switch.

8. The variable capacitor module according to claim 7, wherein, when the switch unit is composed of two or more switches, the switches are connected in series with each other.

9. The variable capacitor module according to claim 2, further comprising a plurality of RF terminals connectable with electrodes included in the plurality of capacitor units.

10. The variable capacitor module according to claim 9, wherein the RF terminals include:
a plurality of first RF terminals connectable with first electrodes included in the plurality of capacitor units; and
a plurality of second RF terminals connectable with second electrodes included in the plurality of capacitor units.

11. The variable capacitor module according to claim 10, wherein any one first RF terminal and any one second RF terminal selected from the plurality of first terminals and second RF terminals are used as an RF input terminal and an RF output terminal, respectively.

12. The variable capacitor module according to claim 10, wherein the first and second RF terminals are electrically insulated from each other.

13. A variable capacitor module, comprising:
a capacitor circuit part including a first capacitor unit and a second capacitor unit connected in parallel with the first capacitor unit; and
a switching circuit part including a first switch unit connected between first electrodes included in the first and second capacitor units and a second switch unit connected between second electrodes included in the first and second capacitor units, and varying a capacitance of the capacitor circuit part by selecting at least one from the first and second capacitor units according to operations of the first and second switch units.

14. The variable capacitor module according to claim 13, further comprising:
1a-th and 1b-th RF terminals connectable to first electrodes included in the first and second capacitor units, respectively; and
2a-th and 2b-th RF terminals connectable to second electrodes included in the first and second capacitor units, respectively.

15. The variable capacitor module according to claim 14, wherein the switching circuit part increases the capacitance of the capacitor circuit part by selecting the first and second capacitor units according to ON operations of the first and second switch units when the 1a-th and 2a-th RF terminals of the first capacitor unit are selected as an RF input terminal and an RF output terminal.

16. The variable capacitor module according to claim 14, wherein the switching circuit part outputs the capacitance of the first capacitor unit as the capacitance of the capacitor circuit part by selecting the first capacitor unit according to OFF operations of the first and second switch units when the 1a-th and 2a-th RF terminals of the first capacitor unit are selected as an RF input terminal and an RF output terminal.

17. A variable capacitor module, comprising:
a capacitor circuit part including 11-th to 13-th capacitor units connected in parallel with each other; and
a switching circuit part including a 11a-th switch unit connected between first electrodes included in the 11-th and 12-th capacitor units; a 12a-th switch unit connected between second electrodes included in the 11-th and 12-th capacitor units; a 11b-th switch unit connected between first electrodes included in the 12-th and 13-th capacitor units; a 12b-th switch unit connected between second electrodes included in the 12-th and 13-th capacitor units; a 11c-th switch unit connected between first electrodes included in the 11-th and 13-th capacitor units; and a 12c-th switch unit connected between second electrodes included in the 11-th and 13-th capacitor units, the switching circuit part varying a capacitance of the capacitor circuit part by selecting at least one capacitor unit from the 11-th to 13-th capacitor units according to operations of the 11a-th to 11c-th switch units and the 12a-th to 12c-th switch units.

18. The variable capacitor module according to claim 17, further comprising:
11c-th, 11b-th, and 11c-th RF terminals connectable to the first electrodes included in the 11-th, 12-th, and 13-th capacitor units, respectively; and
12a-th, 12b-th, and 12c-th RF terminals connectable to the second electrodes included in the 11-th, 12-th, and 13-th capacitor units, respectively.
